(19) United States
(12) Patent Application Publication
(10) Pub. No.: US 2006/0158474 A1
(43) Pub. Date: Jul. 20, 2006

(54) Method and device for accurately positioning a pattern on a substrate

(76) Inventors: Dirkjan Bernhard Van Dam, Eindhoven (NL); Leonardus Johannes Cornelius Van Den Besselaar, Eindhoven (NL)

Correspondence Address: PHILIPS INTELLECTUAL PROPERTY & STANDARDS, P.O. BOX 3001, BRIARCLIFF MANOR, NY, 10510, US

(21) Appl. No.: 10/563,651

(22) PCT Filed: Jul. 1, 2004
(86) PCT No.: PCT/IB04/51091

§ 371 Date: Jan. 6, 2006

(30) Foreign Application Priority Data
Jul. 10, 2003 (EP) 03102093.6

(51) Int. Cl. B41J 29/38

(52) U.S. Cl. 347/16; 347/19

(57) ABSTRACT

A printing machine comprises an X-Y table (50) for moving a substrate (30) with respect to a print head (20). During a printing process, the substrate (30) is moved, whereas the print head (20) is intermittently activated to fire ink droplets. A camera (25) is arranged for providing images of the substrate (30) to a computer which is programmed to recognize patterns. In order for the print head (20) to be able to print a spot at a predetermined position on the substrate (30), an offset between a predetermined and an actual mutual position of the substrate (30) and the print head (20) is measured and compensated for. For the purpose of measuring this offset, a test spot (38) is printed on the substrate (30) and an offset between a predetermined and an actually obtained position of this test spot (38) is measured by means of pattern recognition.

The present invention relates to a method for positioning a substrate and a patterning device at a patterning position with respect to each other, at which position the patterning device is activated to apply a pattern to the substrate.

Processes of applying a pattern to a substrate by means of a patterning device are known in practice, and may be part of a manufacturing process of many types of products. The processes of applying a pattern to a substrate may be carried out in several ways, for example by means of printing or laser writing. In general, printing involves laying down a layer of ink on the substrate, whereas laser writing involves removing portions of the substrate.

For the purpose of being provided with a pattern, a substrate is placed in a patterning machine, in which a patterning device is arranged. Usually, the patterning machine comprises a movable table for supporting and moving the substrate. The pattern forming process takes place by moving the table supporting the substrate with respect to the patterning device and intermittently activating the patterning device. The resulting pattern on the substrate is determined by the output of the patterning device on the one hand, and by the adopted positions of the table supporting the substrate with respect to the patterning device on the other hand.

In a case in which a pattern being composed of a number of layers needs to be formed, the pattern forming process comprises a number of pattern forming steps during which the layers are laid down on the substrate. Each pattern forming step needs to be performed very accurately, in order to avoid a deviation of the different layers and a distortion of the pattern. An example of a pattern forming process comprising a number of pattern forming steps is an ink jet printing process of displays, wherein dimensions of display elements are in the micrometre range. During such a process, it is very important that the positions of the different layers of the pattern on the substrate correspond exactly to each other.

It is an objective of the present invention to provide a method for positioning a substrate and a patterning device with respect to each other, which method is suitable to be applied for the purpose of pattern forming processes in which high standards regarding to the position of the pattern on the substrate need to be met, for example ink jet printing processes of displays. The objective is achieved by means of a method for positioning a substrate and a patterning device at a patterning position with respect to each other, at which position the patterning device is activated to apply a pattern to the substrate, the method comprising the step of determining an actual relation between a patterning position of the substrate and the patterning device with respect to each other and a position of the pattern on the substrate.

By carrying out the method according to the present invention, an actual relation between a patterning position of the substrate and the patterning device with respect to each other and a position of the pattern on the substrate is determined. In a situation in which the pattern needs to be applied to the substrate at a predetermined position, the actual relation is used in order to determine the associated patterning position of the substrate and the patterning device with respect to each other. As a result, it is actually possible to apply the pattern to the substrate at the predetermined position.

When the method according to the present invention is carried out, positioning of the pattern on the substrate is performed in a very accurate way, especially when the method comprises the following steps: positioning the substrate and the patterning device at a predetermined test position with respect to each other; applying a test pattern to the substrate by means of the patterning device; and performing a measurement in order to obtain a result relating to an obtained position of the test pattern on the substrate, wherein the actual relation between a patterning position of the substrate and the patterning device with respect to each other and a position of the pattern on the substrate is determined on the basis of the result which is obtained by the measurement. The result which is obtained by the measurement may for example comprise an actually obtained position of the test pattern on the substrate, or an offset between the actually obtained position of the test pattern on the substrate and a predetermined position of the test pattern on the substrate, wherein the predetermined position of the test pattern on the substrate is determined on the basis of a predetermined relation between a patterning position of the substrate and the patterning device with respect to each other and a position of the pattern on the substrate. Regardless of the exact character of the result which is obtained by the measurement, it is true that the actual relation between a patterning position of the substrate and the patterning device with respect to each other and a position of the pattern on the substrate is determined on the basis of information relating to the predetermined test position on the one hand and information relating to the actually obtained position of the test pattern on the substrate on the other hand.

When the method according to the present invention is carried out by following the steps as mentioned in the preceding paragraph, possible systematic deviations between a position where the pattern is applied to the substrate and an expected position on the basis of the position of the patterning device with respect to the substrate are corrected automatically. Consequently, when the actual relation between a patterning position of the substrate and the patterning device with respect to each other and a position of the pattern on the substrate is used in order to find a required patterning position on the basis of a predetermined position of the pattern on the substrate, the required patterning position is determined in a very accurate way.

The method according to the present invention is particularly suitable to be applied in the field of patterning techniques which involve applying a pattern to a substrate in a manner which is commonly referred to as “direct writing”. Such patterning techniques may involve directly laying down a pattern on a substrate, for example by means of printing, or directly deforming the substrate, for example by means of laser writing.

Further, the method according to the present invention is particularly suitable to be applied in manufacturing processes of displays like PolyLED displays or liquid crystal displays, wherein the displays may be flexible or non-flexible.

The present invention will now be explained in greater detail with reference to the figures, in which similar parts are indicated by the same reference signs, and in which:

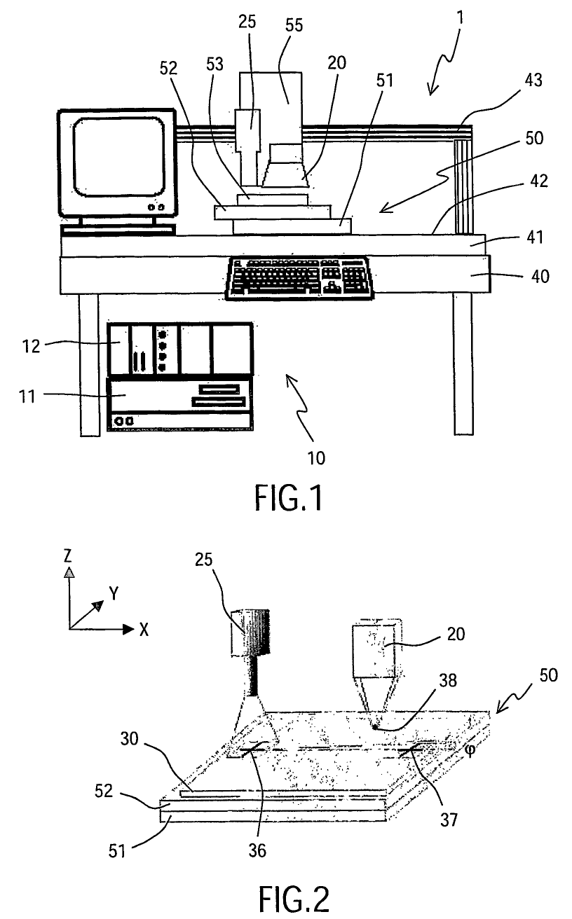

FIG. 1 diagrammatically shows a printing machine comprising a controlling unit for controlling the mutual position of a print head and a substrate;

FIG. 2 diagrammatically shows a perspective view of a number of elements of the printing machine as shown in FIG. 1, as well as the substrate;

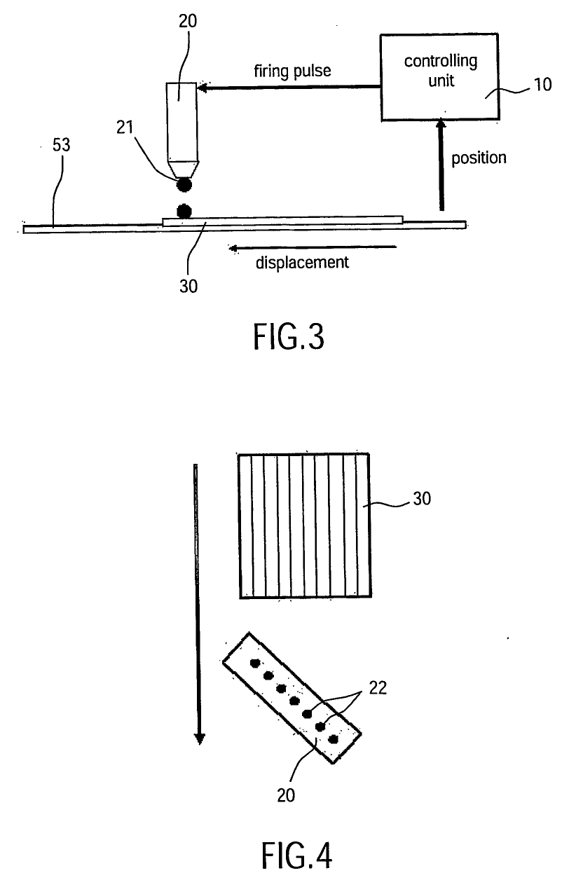

FIG. 3 diagrammatically illustrates the manner in which the printing machine as shown in FIG. 1 works;

FIG. 4 diagrammatically illustrates the position and movement of the substrate with respect to the print head;

FIG. 5 diagrammatically shows an obtained pattern on the substrate; and

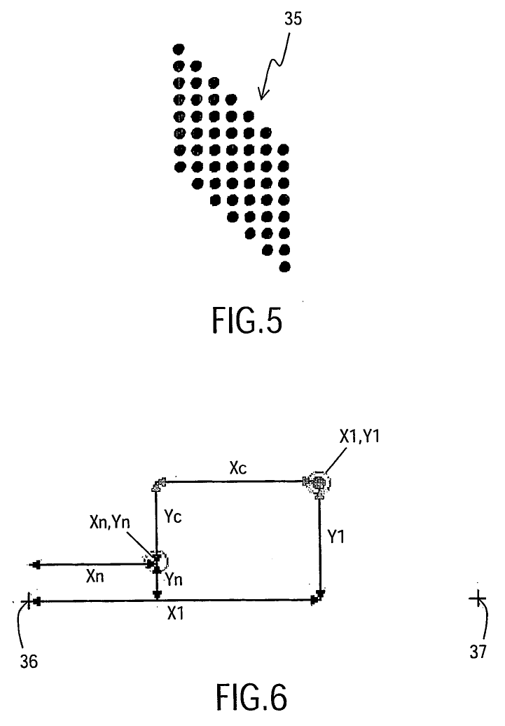

FIG. 6 diagrammatically illustrates the way in which an actual printing position is determined.

FIG. 1 diagrammatically shows a printing machine 1 comprising a controlling unit 10 for controlling the mutual position of a print head 20 and a substrate 30, and FIG. 2 diagrammatically shows the print head 20 and a number of other elements of the printing machine 1, as well as the substrate 30.

The printing machine 1 comprises a table 40 which supports a granite stone 41. On top of the stone 41, an X-Y table 50 is mounted. An X-direction and a Y-direction correspond to directions in a plane in which an upper surface 42 of the stone 41 extends, wherein the X-direction and the Y-direction are perpendicular with respect to each other. In FIG. 2, the X-direction and the Y-direction are indicated by means of an arrow X and an arrow Y, respectively. The X-Y table 50 comprises an X-table 51 which is movable in the X-direction and a Y-table 52 which is movable in the Y-direction. On top of the X-Y table 50, a substrate holder 53 for holding and supporting the substrate 30 is positioned.

Further, the printing machine 1 comprises a portal 43 and a Z-slide 55 which is suspended from the portal 43. A Z-direction is perpendicular to both the X-direction and the Y-direction. In FIG. 2, the Z-direction is indicated by means of an arrow Z. The Z-slide is movable in the Z-direction and supports the print head 20 and a camera 25.

For the purpose of controlling the movements of the X-Y table 50 and the Z-slide 55, the controlling unit 10 of the printing machine 1 comprises a computer 11 and motor controlling members 12. During operation of the printing machine 1, the computer 11 determines the required positions and movements of the X-table 51, the Y-table 52 and the Z-slide 55, and transmits signals representing the required movements to the motor controlling members 12. On the basis of the received signals, the motor controlling members 12 control the operation of motors (not shown) driving the X-table 51, the Y-table 52 and the Z-slide 55.

Advantageously, the printing machine 1 comprises an exhauster (not shown) located near the X-Y table 50 and the substrate holder 53 for exhausting harmful gases which may be released during a printing process.

In the following, the manner in which the printing machine 1 works is explained with reference to FIG. 3.

FIG. 3 diagrammatically shows the substrate holder 53, the substrate 30, the print head 20 and the controlling unit 10. During a printing process, the controlling unit 10 controls the displacement of the substrate holder 53, as well as the functioning of the print head 20 on the basis of the position of the substrate 30. When the substrate 30 and the print head 20 are at a printing position with respect to each other, the controlling unit 10 transmits a firing pulse to the print head 20. As soon as the print head 20 receives the firing pulse, the print head 20 fires an ink droplet 21 in the direction of the substrate 30. By repeating this process, a printed pattern is formed on the substrate 30.

A possible configuration of the print head 20 and the substrate 30 is shown in FIG. 4, which diagrammatically shows a top view of the print head 20 and the substrate 30. The print head 20 as diagrammatically shown in FIG. 4 comprises a number of nozzles 22, which are indicated by means of dots. Each nozzle 22 is controlled by the controlling unit 10, and is capable of firing an ink droplet 21 on receipt of a firing pulse of the controlling unit 10. When the substrate 30 is moved with respect to the print head 20 in the direction as indicated by an arrow in FIG. 4, and the nozzles 22 of the print head 20 are controlled to intermittently release ink droplets 21, a printed pattern 35 as shown in FIG. 5 is obtained. Characteristics of the printing process influencing the appearance of the pattern 35 as such are a firing frequency of the nozzles 22 of the print head 20 and characteristics of a movement of the substrate 30 with respect to the print head 20. Characteristics of the printing process influencing the position of the pattern 35 on the substrate 30 are the adopted positions of the substrate 30 with respect to the print head 20 and the direction in which the ink droplets 21 are released by the nozzles 22 of the print head 20.

Within the scope of the present invention, numerous possibilities for the appearance of the pattern 35 exist. For example, the pattern 35 may comprise one spot or a plurality of spots, and may in the latter case be regular or irregular.

The method of providing a substrate 30 with a pattern 35 as described in the foregoing, in which the pattern 35 is obtained by moving the substrate 30 with respect to a print head 20 and intermittently releasing ink droplets 21 in the direction of the substrate 30 by means of the print head 20, may for example be applied for the purpose of manufacturing displays, in particular so-called PolyLED displays. PolyLED displays comprise a large number of light emitting diodes, wherein each light emitting diode (commonly referred to as LED) comprises a stack of individual layers. A number of these layers is formed by dosing the material of these layers dissolved in a solvent in a pixel, wherein a pixel is a limited area having predetermined dimensions. It will be understood that the ink droplets 21 which are released by the print head 20 for the purpose of providing the substrate 30 with the layers comprise the said solvent and the said material of the layers.

In the field of PolyLED displays, substrates 30 comprising glass are normally utilized. Suitable values for the diameter of the pixels and the mutual distance of the pixels are 50 μm and 200 μm, respectively.

For the purpose of the above-described application during the manufacturing process of PolyLED displays, the printing process has to meet very high requirements. An important requirement is that the patterns 35 of the individual layers are positioned very accurately with respect to each other, so that a deviation of these patterns 35 is avoided. Usually, pre-patterned substrates 30 are applied, and it is important that the printed pattern 35 is accurately positioned with respect to the pattern which is already present on the substrate 30. In order to meet these requirements, the positioning of the printed pattern 35 on the substrate 30 needs to be performed very accurately.

The required position of the pattern 35 on the substrate 30 is stored in the computer 11 of the controlling unit 10. During the printing process, the computer 11 controls the position of the substrate 30 with respect to the print head 20 through the motor controlling members 12, such that the obtained position of the pattern 35 on the substrate 30 corresponds to the required position of the pattern 35 on the substrate 30. During the process, a number of practical errors needs to be compensated for, which errors comprise errors relating to the position of the substrate 30 with respect to the X-Y table 50 and the position of the print head 20 with respect to the X-Y table 50. The present invention proposes a printing method in which a number of important errors are compensated for, such that an accurate positioning of the pattern 35 on the substrate 30 may be realized, and that the printing method is applicable in the field of printing displays. In the following, a preferred way of carrying out the method according to the present invention is described, with reference to FIGS. 2 and 6. For the sake of simplicity, FIG. 2 does not show the substrate holder 53. In the example as shown in FIG. 2, the print head 20 comprises a single nozzle 22, contrary to the example as shown in FIG. 4, which already has been discussed in the foregoing. This underlines the fact that the application of the method according to the present invention is not dependent on the number of nozzles 22 of the print head 20.

Before the printing process can take place, the substrate 30 is placed onto the substrate holder 53 in the printing machine 1. In this process, the substrate 30 is roughly put at a predetermined position with respect to the substrate holder 53 in any known suitable way, for example with the help of fixed pens on the substrate holder 53. At the side of the substrate 30 which needs printing, two reference markers 36, 37 are present on the substrate 30.

When the substrate 30 is positioned on the substrate holder 53 in a proper manner, an aligning process is started. As a first step in the aligning process, the X-Y table 50 is moved, and the computer searches for the reference markers 36, 37 on the substrate 30 with the help of the camera 25. The computer comprises an imaging card for capturing images from the camera 25, as well as software for recognizing and processing the images. The software has learned the appearance of the marks 36, 37, and is capable of searching for a match of the learned appearance in images which are captured from the camera 25. In this way, the computer 11 is able to determine the position of the reference markers 36, 37 with respect to the X-Y table 50.

An offset of the positions of the individual reference markers 36, 37 with respect to the X-Y table 50 is compensated for by setting one of the reference markers 36, 37, for example reference marker 36, as a new zero position having X-Y coordinates (0,0). An angle φ between an imaginary reference line extending through both reference markers 36, 37 and the X-direction, in other words, an angle φ of substrate rotation, is determined on the basis of a comparison of the positions of the individual marks 36, 37. As the X-Y coordinates of reference marker 36 are set as (0,0), the rotation angle φ can simply be found as the tangent of the outcome of the division of the Y-coordinate of reference marker 37 by the X-coordinate of reference marker 37. The rotation angle φ is used in a process of calculating an actual printing position of the X-Y table 50 on the basis of a predetermined position of a printed spot on the substrate 30, in a manner which will be described in the following. The actual printing position may be regarded as the position which actually needs to be adopted by the X-Y table 50 in order for the print head 20 to be able to print the spot at the predetermined position on the substrate 30.

For the purpose of performing a second step in the aligning process, the computer 11 of the controlling unit 10 is programmed such as to move the X-Y table 50 towards a predetermined test position with respect to the new zero position. As soon as the X-Y table 50 has adopted the predetermined test position, the print head 20 is activated by the computer 11 to release an ink droplet 21. The released ink droplet 21 forms a test spot 38 on the substrate 30. This test spot 38 is printed at an area of the substrate 30 which is not intended for receiving the functional printed pattern 35, i.e. the printed pattern 35 which is intended to actually perform a function when the manufacturing process is finished and the printed substrate 30 is applied for the purpose it has been designed for.

Once the test spot 38 has been printed, it is possible to measure an offset between a predetermined position and the actually obtained position of the test spot 38. This offset is also determined in an optical manner using pattern recognition, with the help of the camera 25 and a search to a previously learned appearance of the test spot 38.

On the basis of the determined rotation angle φ and the measured offset between the predetermined position and the actually obtained position of the test spot 38, the computer 11 of the controlling unit 10 is capable of determining an actual printing position of the X-Y table 50 for the purpose of printing a spot at a predetermined position on the substrate 30. In the following, the way in which the computer 11 determines the actual printing position of the X-Y table 50 is explained, wherein reference is made to FIG. 6, and wherein the following symbols are used:
Xh=offset between the predetermined position and the actually obtained position of the test spot 38 in the X-direction;
Yh=offset between the predetermined position and the actually obtained position of the test spot 38 in the Y-direction;
Xc=corrected offset between the predetermined position and the actually obtained position of the test spot 38 in the X-direction;
Yc=corrected offset between the predetermined position and the actually obtained position of the test spot 38 in the Y-direction;
X1=X-coordinate of the predetermined position of the spot with respect to reference marker 36;
Y1=Y-coordinate of the predetermined position of the spot with respect to reference marker 36;
Xn=X-coordinate of the actual printing position of the X-Y table 50 before compensation for rotation angle φ;
Yn=Y-coordinate of the actual printing position of the X-Y table 50 before compensation for rotation angle φ;
Xp=X-coordinate of the actual printing position of the X-Y table 50; and
Yp=Y-coordinate of the actual printing position of the X-Y table 50.

First of all, the measured offset between the predetermined position and the actually obtained position of the test spot 38 needs to be corrected for rotation angle φ. The reason for this is that during the printing of the test spot 38, the substrate 30 has been at a position which did not exactly correspond to the predetermined test position, due to the influence of the rotation of the substrate 30 with respect to the X-Y table 50. The coordinates of the corrected offset are determined by means of the following formula:
Xc=\sqrt{Xh²+Yh²}*sin(φ+arctan(Xh,Yh))
Yc=\sqrt{Xh²+Yh²}*cos(φ+arctan(Xh, Yh))

Using the corrected offset, the actual printing position of the X-Y table 50 can be determined in two steps. In the first step, the corrected offset is taken into account, whereas in the second step, the rotation angle φ is taken into account.

$$Xn = X 1 - Xc$$

$$Yn = Y 1 - Yc \\ [ \begin{matrix}Xp \\ Yp\end{matrix} ] = [ \begin{matrix}Xn \\ Yn\end{matrix} ] * [ \begin{matrix}cos φ & - sin φ \\ sin φ & cos φ\end{matrix} ]$$

On the basis of the calculated values of Xp and Yp, the computer 11 of the controlling unit 10 controls the motors driving the X-table 51 and the Y-table 52 through the motor controlling members 12, such that the X-Y table 50 adopts the actual printing position. When the X-Y table 50 has reached the actual printing position, the printing process can be started by activating the print head 20, whereupon at least one ink droplet 21 is fired, which forms a spot on the substrate 30 at the predetermined position with respect to reference marker 36.

In fact, the aligning process involves determining an actual relation between the actual printing position of the X-Y table 50 and the predetermined position of the spot with respect to reference marker 36, on the basis of which the computer 11 is able to determine the actual printing positions which are required for the purpose of printing a pattern 35, taking into account the fact that the pattern 35 may be regarded as a collection of spots.

In principle, the aligning process needs to be performed only once per substrate 30, before the printing process takes place, especially in case of the substrate 30 being relatively small. The computer 11 is capable of storing the measured rotation angle φ and the measured offset between the predetermined position and the actually obtained position of the test spot 38. On the basis of these two parameters, the computer 11 is able to calculate the actual printing positions of the X-Y table 50 for an entire pattern which needs to be printed on the substrate 30. Nevertheless, for the purpose of printing a pattern 35 on a relatively large substrate 30, the aligning process is preferably performed a number of times, not only before the printing process is started, but also at certain stages of the printing process. For each aligning process, a different predetermined test position may be used in the process of printing a test spot 38 on the substrate 30. By carrying out the aligning process a number of times for one substrate 30, it is possible to position the pattern 35 very accurately with respect to the reference markers 36, 37, while changes in the functioning of the nozzle 22 of the print head 20, which occur over time, are corrected for.

An important advantage of the above-described aligning process is that the process is completely automated. After the substrate 30 has been placed on the substrate holder 53, the computer 11 performs the aligning process with the help of the camera 25, wherein no human interference is needed.

When the aligning process comprises the above-described step of printing a test spot 38 and measuring an offset between a predetermined position and an actually obtained position of the test spot 38, possible systematic deviations between the actually obtained position of the test spot 38 and an expected position on the basis of the position of the print head 20 are corrected automatically.

The aligning process may be carried out in various ways. For example, it is not necessary that the markers 36, 37 are searched first, and that the test spot 38 is printed later; these steps of the aligning process may be carried out in reverse order.

It is not essential that the aligning process comprises the step of measuring an offset between the predetermined position and the actually obtained position of the test spot 38. According to another feasible possibility, the test spot 38 is searched with the help of the camera 25, and as soon as the test spot 38 is found, the actually obtained position of the test spot 38 is measured. On the basis of the combination of this actually obtained position of the test spot 38 and the set test position of the X-Y table 50, it is possible to determine a relation between a set printing position of the X-Y table 50 and an obtained position of a spot on the substrate 30. Using this relation, the computer 11 of the controlling unit 10 is capable of controlling the position of the substrate 30 with respect to the print head 20 and the operation of the print head 20 such that a pattern 35 is obtained at a predetermined position on the substrate 30. Although measuring the actually obtained position of the test spot 38 yields good results as well, this way of carrying out the aligning process has a drawback relating to the fact that the time needed for finding the test spot 38 is increased.

The aligning process may also be used in situations in which a print head 20 comprising a plurality of nozzles 22 is applied. In such a case, the aligning process may comprise a step during which the X-Y table 50 is moved to a predetermined test position and all nozzles 22 of the print head 20 are activated to release an ink droplet 21. Consequently, a test row instead of a test spot 38 is obtained on the substrate 30. The image learned by the computer 11, which is used to search for the test row, preferably comprises an end portion of the test row and an adjacent blank portion. The end portion of the test row may for example comprise two spots. The dimensions of the adjacent blank portion in the direction in which the test row extends should exceed the distance between two subsequent spots, so that the computer 11 is able to directly find the end portion of the test row. In this way, the computer 11 is able to measure an offset between the predetermined position and an actually obtained position of the test row. Additionally, the computer 11 may also be programmed to find a deviation between a predetermined direction of the test row and an actually obtained direction of the test row, in order to determine a rotation angle between the row of nozzles 22 of the print head 20 and the X-Y table 50. In case this rotation angle is determined, it is preferred to use an X-Y-φ table instead of an X-Y table 50 for moving the substrate 30, so that the rotation angle may be compensated for by means of a rotation of the X-Y-φ table.

Another possibility in the context of multiple nozzles 22 is that the computer 11 is programmed to determine the offset between a predetermined position and the actually obtained position of each test spot 38 that is part of the test row, or to determine the actually obtained position of each test spot 38. In this way, the computer 11 is capable of determining a relation between a printing position of the table supporting the substrate 30 and an obtained position of a printed spot on the substrate 30, for each individual nozzle 22. On the basis of this relation, the computer 11 is capable of controlling the printing process such that the required pattern 35 is accurately laid down on the substrate 30, wherein the accuracy of both the mutual positions of the spots of the pattern 35 and the position of the pattern 35 on the substrate 30 meets the requirements. In fact, in this way, the aligning process as described in the foregoing in the context of a print head 20 having one single nozzle 22 is performed for each individual nozzle 22 of the print head 20 having more than one nozzle 22.

As a result of the process as described in the preceding paragraph, in practice, the nozzles 22 are not activated at exactly the same time, as the actual relation between a printing position of the table and an obtained position of a printed spot on the substrate 30 associated with one nozzle 22 differs from the said relation associated with another nozzle 22. The computer 11 may even be programmed not to use all nozzles 22, in case it appears from the aligning process that one or more nozzles 22 do not function properly. In such a case, the computer 11 controls the nozzles 22 of the print head 20 such that the function of the malfunctioning nozzles 22 is taken over by other nozzles 22, so that the obtained pattern 35 on the substrate 30 is not interrupted.

It will be clear to a person skilled in the art that the scope of the present invention is not limited to the examples discussed in the foregoing, but that several amendments and modifications thereof are possible without deviating from the scope of the present invention as defined in the attached claims.

The shown printing machine 1 comprises an X-Y table 50 for moving the substrate 30 for the purpose of positioning the substrate 30 and the print head 20 with respect to each other and for the purpose of positioning the substrate 30 and the camera 25 with respect to each other. Both the print head 20 and the camera 25 are only movable in the Z-direction by means of the Z-slide 55. In principle, within the scope of the present invention, it is also possible that the print head 20 and the camera 25 are movable in the X-direction and the Y-direction, whereas the position of the substrate 30 is fixed in said directions. It is even possible that all of the print head 20, the camera 25 and the substrate 30 are movable in the X-direction and the Y-direction. However, the arrangement as shown is preferred over the other possibilities. It is important that the substrate 30 and the print head 20 are movable with respect to each other in the X-direction and the Y-direction, and the same is true for the substrate 30 and the camera 25. All possible manners in which this can be realized, are within the scope of the present invention.

In the shown example, a single camera 25 is used for detecting the markers 36, 37 and the printed test spot 38. It will be understood that it is possible to apply more than one camera 25. However, in such a case, the accuracy of positioning the substrate 30 and the print head 20 with respect to each other is negatively influenced by errors in the mutual position of the cameras 25. Therefore, these errors are preferably determined and accounted for.

It is not necessary that a camera 25 is used for detecting the markers 36, 37 and the test spot 38. Depending on the character of the markers 36, 37 and the test spot 38, another kind of detecting means may be applied, for example an infra red camera or even a tracer in case of the markers 36, 37 and/or the test spot 38 comprising an unevenness on the substrate 30.

In the foregoing, the present invention is described in the context of printing, in particular printing displays. This does not mean that the present invention is not applicable to other ways of providing a substrate with a pattern. On the contrary, the present invention is also applicable in the fields of for example laser writing, wherein the method according to the present invention may be used to accurately position a mask with respect to a substrate. In fact, the present invention is applicable in every situation in which a substrate needs to be provided with a pattern and in which a patterning device is used, which needs to be accurately positioned with respect to the substrate.

During one step of the aligning method, an angle φ of a rotation of the substrate 30 with respect to the X-Y table 50 is determined, as described in the foregoing. For the purpose of calculating the actual printing position of the X-Y table 50, the rotation angle φ is taken into account. Instead of compensating for the rotation angle φ by adjusting the actual printing position of the X-Y table 50, it is also possible to apply an X-Y-φ table. In case of such a table being part of the printing machine 1, the measured rotation angle φ can be compensated for by a rotation of a φ-table of the X-Y-φ table.

Application of the method according to the present invention yields accurately patterned final products. The final product is not only provided with a functional pattern, i.e. the pattern by which the final product is able to perform an assigned task, but also with a test pattern, which has only been of use during the manufacturing process of the product.

In the foregoing, a printing machine 1 is described, which comprises an X-Y table 50 for moving a substrate 30 with respect to a print head 20 in an X-direction and a Y-direction. During a printing process, the substrate 30 is moved, whereas the print head 20 is intermittently activated to fire ink droplets 21 in order to form a pattern 35 on the substrate 30.

At a distance from the print head 20, a camera 25 is arranged for providing images of the substrate 30 to a computer 11 which is programmed to recognize patterns. In order for the print head 20 to be able to print a spot at a predetermined position on the substrate 30, an offset between a predetermined mutual position of the substrate 30 and the print head 20 and an actual mutual position of the substrate 30 and the print head 20 is measured and compensated for. For the purpose of measuring this offset, a test spot 38 is printed on the substrate 30 and an offset between a predetermined position and an actually obtained position of this test spot 38 is measured by means of pattern recognition.

1. Method for positioning a substrate (30) and a patterning device (20) at a patterning position with respect to each other, at which position the patterning device (20) is activated to apply a pattern (35) to the substrate (30), the method comprising the step of determining an actual relation between a patterning position of the substrate (30) and the patterning device (20) with respect to each other and a position of the pattern (35) on the substrate (30).

2. Method according to claim 1, comprising the following steps:
positioning the substrate (30) and the patterning device (20) at a predetermined test position with respect to each other;
applying a test pattern (38) to the substrate (30) by means of the patterning device (20); and
performing a measurement in order to obtain a result relating to an actually obtained position of the test pattern (38) on the substrate (30), wherein the actual relation between a patterning position of the substrate (30) and the patterning device (20) with respect to each other and a position of the pattern (35) on the substrate (30) is determined on the basis of the result which is obtained by the measurement.

3. Method according to claim 2, wherein the measurement is performed in an optical manner using pattern recognition.

4. Method according to claim 2, wherein an offset between an actually obtained position of the test pattern (38) on the substrate (30) and a predetermined position of the test pattern (38) on the substrate (30) is measured, wherein the predetermined position of the test pattern (38) on the substrate (30) is determined on the basis of a predetermined relation between a patterning position of the substrate (30) and the patterning device (20) with respect to each other and a position of the pattern (35) on the substrate (30), and wherein the actual relation between a patterning position of the substrate (30) and the patterning device (20) with respect to each other and a position of the pattern (35) on the substrate (30) is determined by correcting the predetermined relation for the offset as measured.

5. Method according to claim 2, wherein an actually obtained position of the test pattern (38) on the substrate (30) is measured, and wherein the actual relation between a patterning position of the substrate (30) and the patterning device (20) with respect to each other and a position of the pattern (35) on the substrate (30) is determined by linking the actually obtained position of the test pattern (38) on the substrate (30) as measured to the predetermined test position.

6. Method according to claim 1, comprising the step of determining a rotation angle (φ) between an actual straight line of movement of the substrate (30) and the patterning device (20) with respect to each other and a predetermined straight line of movement of the substrate (30) and the patterning device (20) with respect to each other, wherein the actual relation between a patterning position of the substrate (30) and the patterning device (20) with respect to each other and a position of the pattern (35) on the substrate (30) is corrected for the rotation angle (φ).

7. Method according to claim 6, wherein the rotation angle (φ) is determined in an optical manner using pattern recognition.

8. Method according to claim 6, wherein the predetermined straight line of movement of the substrate (30) and the patterning device (20) with respect to each other is indicated on the substrate (30) by means of two reference markers (36, 37).

9. Method according to claim 8, wherein the rotation angle (φ) is determined by moving the substrate (30) and the patterning device (20) with respect to each other according to the actual straight line of movement and comparing the positions of the reference markers (36, 37) in a direction substantially perpendicular to the actual straight line of movement.

10. Method according to claim 1, applied for the purpose of printing displays, in particular PolyLED displays or liquid crystal displays, wherein the patterning device comprises a print head (20) having at least one nozzle (22) for releasing ink droplets (21).

11. Patterning machine (1), suitable for carrying out the method according to claim 1, comprising:
a first receiving member (53) for receiving a substrate (30);
a second receiving member for receiving a patterning device (20) for applying a pattern (35) to the substrate (30);
moving means (50) for moving the substrate (30) and the patterning device (20) with respect to each other;
a computer (11); and
detecting means for detecting markers (36, 37) and patterns (38) on the substrate (30), wherein the computer (11) is programmed such as to recognize the markers (36, 37) and the patterns (38) and to determine positions of the markers (36, 37) and the patterns (38) with respect to the moving means (50).

12. Patterning machine (1) according to claim 11, wherein the detecting means comprise at least one camera (25) for providing images of the substrate (30) to the computer (11), and wherein the computer (11) is programmed such as to capture the images from the camera (25), as well as to recognize the images.

13. Patterning machine (1) according to claim 12, wherein the computer (11) is programmed such as to perform an aligning process comprising the following steps:
controlling the moving means (50) such as to position the substrate (30) and the patterning device (20) at a predetermined test position with respect to each other;
transmitting an activating pulse to the patterning device (20) in order to apply a test pattern (38) to the substrate (30);
controlling the moving means (50) such as to position the substrate (30) and the camera (25) at the predetermined test position with respect to each other; and
measuring an offset between an actually obtained position of the test pattern (38) and a predetermined position of the test pattern (38) by means of the camera (25), using pattern recognition.

14. Patterning machine (1) according to claim 12, wherein the computer (11) is programmed such as to perform an aligning process comprising the following steps:
controlling the moving means (50) such as to position the substrate (30) and the patterning device (20) at a predetermined test position with respect to each other;
transmitting an activating pulse to the patterning device (20) in order to apply a test pattern (38) to the substrate (30);
detecting an actually obtained position of the test pattern (38) on the substrate (30) by means of the camera (25), using pattern recognition.

15. Patterning machine (1) according to claim 13, wherein the computer (11) is programmed to perform the aligning process more than one time for one substrate (30), and wherein the aligning process is alternated with a process during which a pattern (35) is applied to the substrate (30) by means of the patterning device (20).

16. Patterning machine (1) according to claim 11, wherein the moving means comprise an X-Y table (50).

17. Patterning machine (1) according to claim 11, wherein the patterning device comprises a print head (20) having at least one nozzle (22) for releasing ink droplets (21).

18. Printed display, in particular a PolyLED display or a liquid crystal display, comprising at least two reference markers (36, 37) and a printed test pattern (38) which is positioned outside an area having a functional pattern (35) which serves for displaying an image.
